(19) United States
(12) Patent Application Publication
(10) Pub. No.: US 2004/0032247 A1
(43) Pub. Date: Feb. 19, 2004

(54) Modified construct of testing fixture to improve hermetic seal

(76) Inventors: Han-Ying Chen, Chupei City (TW); Jin-Long Lin, Hsinchu (TW)

Correspondence Address: VENABLE, BAETJER, HOWARD AND CIVILETTI, LLP, P.O. BOX 34385, WASHINGTON, DC, 20043-9998, US

(21) Appl. No.: 10/217,610

(22) Filed: Aug. 14, 2002

(51) Int. Cl. G01R 1/00

(52) U.S. Cl. 324/158.1

(57) ABSTRACT

A modified construct of testing fixture to improve hermetic seal is disclosed. The construct of the testing fixture comprises a cylindrical body, made of Kovar alloy, a ceramic bottom plate and a cover plate, together creating an internal cavity to accommodate an integrated device to be tested. Multiple connecting pins made of Kovar alloy are soldered into through holes on the bottom plate. The integrated device to be tested is loaded up and placed into the cavity of the cylindrical body, and then a cover plate is used to seal off the opening and to make the connecting pins contact the integrated device to establish signal connection with the internal circuits of the integrated device. The modified construct of the testing fixture is able to keep the integrated device hermetically sealed during circuit testing, thus preventing water vapor and dust from getting in.

### BACKGROUND OF THE INVENTION

1. Field of the Invention

The present invention relates to a modified construct of testing fixture to improve hermetic seal, especially to a modified structural design that is capable of maintaining a perfect hermetic seal in the die-test cavity of a testing fixture.

2. Description of Related Arts

FIG. 5 is the diagram of the construct of a conventional testing fixture, which comprises a cylindrical body (70) made of Kovar alloy (composing of iron, cobalt, and nickel) containing a die-test cavity (71) for loading an integrated device to be tested, a gas nozzle (73) and multiple connecting pins (72) soldered into the through holes of the bottom plate. The connecting pins (72) are extended from the outside into the die-test cavity (71) through the above-mentioned holes in the bottom plate, such that one end is able to make signal connection with the internal circuits of the integrated device, while the other end outside the testing fixture is to be connected to the testing equipment.

When an integrated device is loaded up and placed into the die-test cavity (71), the opening of the die-test cavity (71) is sealed off by a cover plate (not specifically identified in the diagram) to prevent water vapor and dust from getting in, and internal air is pumped out through the gas nozzle (73) located at the bottom of the cylindrical body (70) thus creating a vacuum in the die-test cavity (71) in preparation for a circuit testing on the integrated device. However, the space in the conventional testing fixture is not completely a vacuum, a critical condition that could affect the accuracy of the test report, because there are air space in the die-test cavity (71) even after sealing off the opening.

The problem is caused by an intermediate sealing medium, which is made of different materials and exhibits different thermal expansion when subject to high temperature. According to the conventional way, the cylindrical body (70) including the bottom is made of Kovar alloy, therefore the metallic connecting pins (72) on the bottom need to be insulated to prevent short circuits. Multiple through holes (74) are first formed in the bottom plate, and then connecting pins (72) are sealed into the through holes (74) by fritted glass (75). With reference to FIG. 6, the sealing fritted glass (75) becomes the intermediate medium, which acts to insulate the connecting pin (72) from the metal bottom of the cylindrical body (70). But the connecting pins (72) and the bottom of the cylindrical body (70) are both made of metal which has a different thermal expansion characteristic as compared with the intermediate glass material. Air gaps are formed in between the glass portion (75) and the metal portion around the through hole (74), allowing air to leak in and alter the vacuum condition in the die-test cavity (71).

### SUMMARY OF THE INVENTION

The main object of the present invention is to provide a modified construct of testing fixture with an improved hermetic seal to ensure a perfect vacuum for circuit testing of integrated devices. The modified fixture comprises a cylindrical body made of Kovar alloy, which is closed off on both ends by a ceramic bottom plate and a cover plate respectively.

The surface of the bottom plate has multiple metallized through holes, in which metallic connecting pins are soldered, the position of which is to make contact with the integrated device to be tested to cause signal connection with the internal circuits of the integrated device.

Since the bottom plate is made of insulated ceramic material, metal connecting pins can be soldered on the ceramic bottom plate directly with no need of an intermediate medium. Such construct assembling of the connecting pins and the bottom plate could prevent air gaps in thermal expansion, thus assuring a hermetic seal in the die-test cavity.

The bottom plate has at least one gas nozzle created on the surface for pumping out the air from the closed off cavity before the circuit testing is performed.

The bottom plate also has multiple ground lines distributed on the surface and on the perimeter, which are connected to a common ground; wherein the ground line on the surface of the bottom plate is connected to one of the connecting pins to be a grounding terminal.

The bottom plate also has a metal shielding zone created over the central area of the bottom plate, the position of which corresponds to the integrated device to be placed in the cavity of the cylindrical body. The shielding zone is connected to ground to protect the integrated device against EMI.

The features and structure of the present invention will be more clearly understood when taken in conjunction with the accompanying figures.

### BRIEF DESCRIPTION OF THE DRAWINGS

FIG. 1 is an exploded diagram of the present invention;

FIG. 2 is a perspective view of the invention;

FIG. 3 is a cross-sectional view of the assembled device in accordance with the present invention;

FIG. 4 is a bottom view of the invention;

FIG. 5 is a cross-sectional view of a conventional device; and

FIG. 6 is a bottom view of the conventional device.

### DETAILED DESCRIPTION OF THE PREFERRED EMBODIMENT

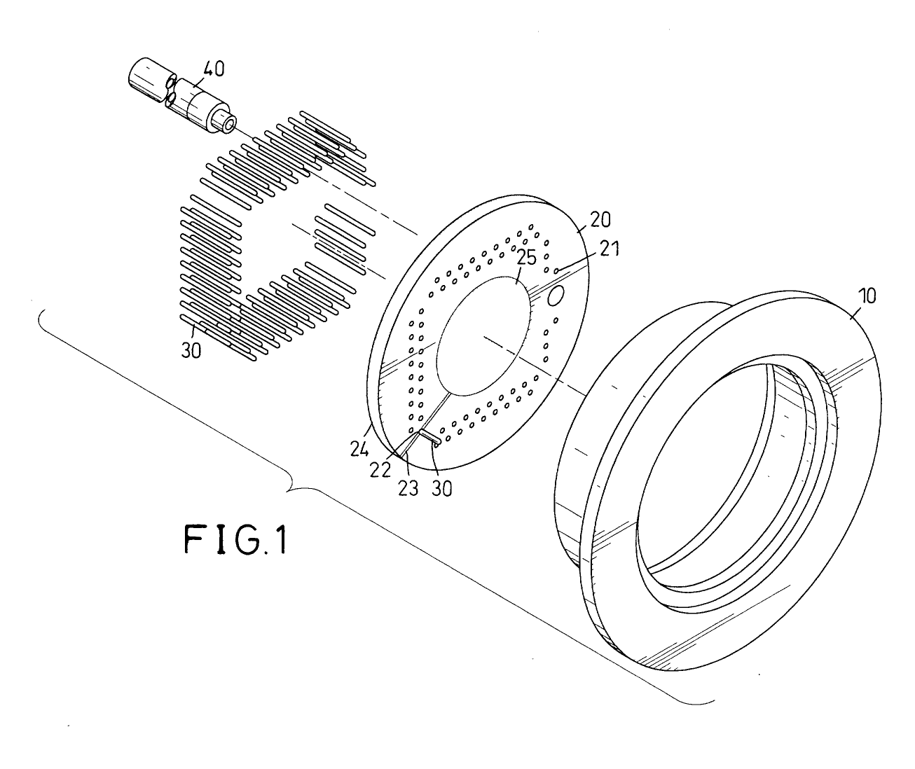

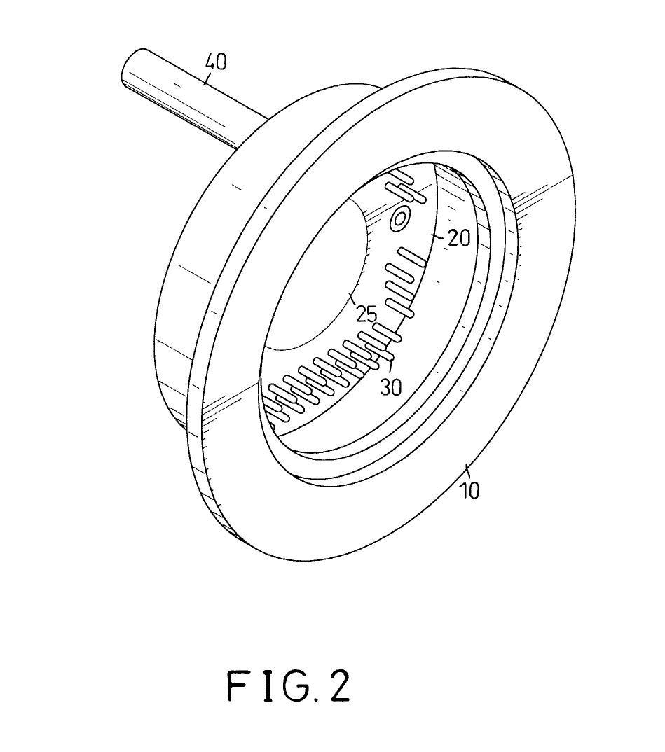

With reference to FIGS. 1 and 2, the present invention applies to a modified construct of a testing fixture to improve its hermetic seal, basically comprising a cylindrical body (10), a ceramic bottom plate (20) and a cover plate (not shown).

The cylindrical body (10) made of Kovar alloy possesses a hollow central portion (in the current embodiment), with openings respectively at the top and bottom.

The round bottom plate (20) made of insulated material such as sintered ceramic is placed over the bottom opening of the cylindrical body (10) and seal welded, over which multiple connecting pins (30) made of Kovar alloy and a gas nozzle (40) are protruded out from through hole (21, 22).

The connecting pins (30) are placed in contact with an integrated device to be tested to cause signal connection with the internal circuits of the integrated device, while the gas nozzle (40) is used for pumping out the air from the cavity (not specifically identified in the diagram) after closing the top opening of the cylindrical body (10) with a cover plate (not specifically identified in the diagram).

The round cover plate (not specifically identified in the diagram) is placed over the top opening of the cylindrical body (10) to close off the cavity (not specifically identified in the diagram) from the outside environment.

The connecting pins (30) and the gas nozzle (40) of the bottom plate (20) are sealed into the metallized through holes (21, 22) respectively. Having the side walls of the holes (21, 22) electroplated would facilitate the soldering of the connecting pin (30) onto the bottom plate (20).

Multiple ground lines (23, 24) are distributed on the surface and the perimeter of the bottom plate (20), and are connected to a common ground, wherein the ground line (23) on the surface of the ceramic bottom plate (20) is connected to one of the metallic through holes (22), through which one of the connecting pins (30) is inserted forming a grounding terminal; whereas the ground line (24) on the perimeter of the bottom plate (20) is connected to the cylindrical body (10) made of Kovar alloy after the bottom plate (20) is sealed off along the bottom opening of the cylindrical body (10).

A metallized shielding zone (25) is created over the central area of the ceramic bottom plate (20), surrounded by the connecting pins (22), such that the position of the shielding zone (25) corresponds to the internal circuits of the integrated device to be loaded onto the die-test cavity (not specifically identified in the diagram) of the cylindrical body (10). The shielding zone (25) is connected to the ground line (23, 24), thus forming a protective shielding for the tested integrated device against EMI.

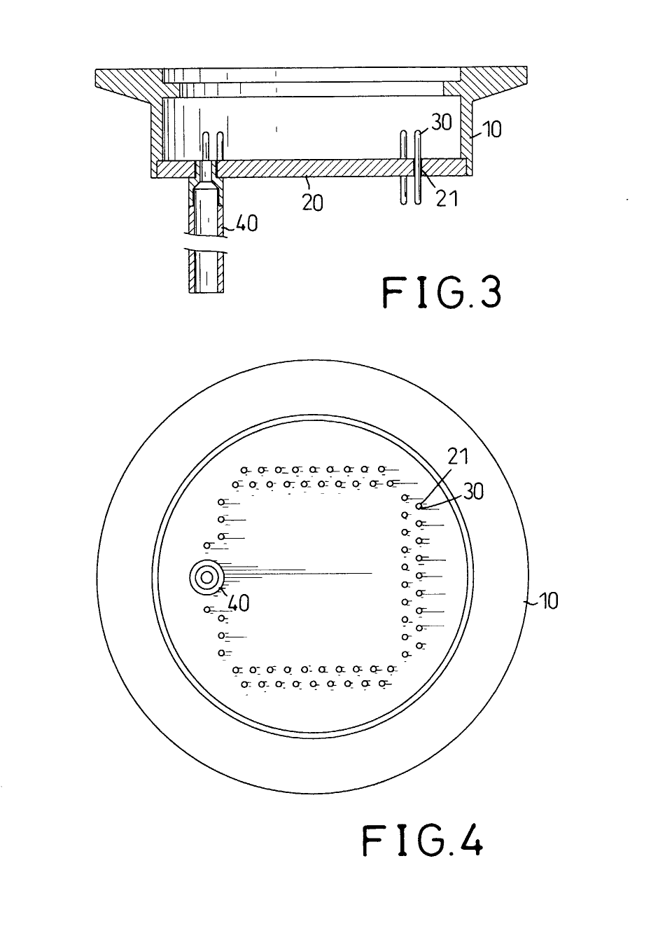

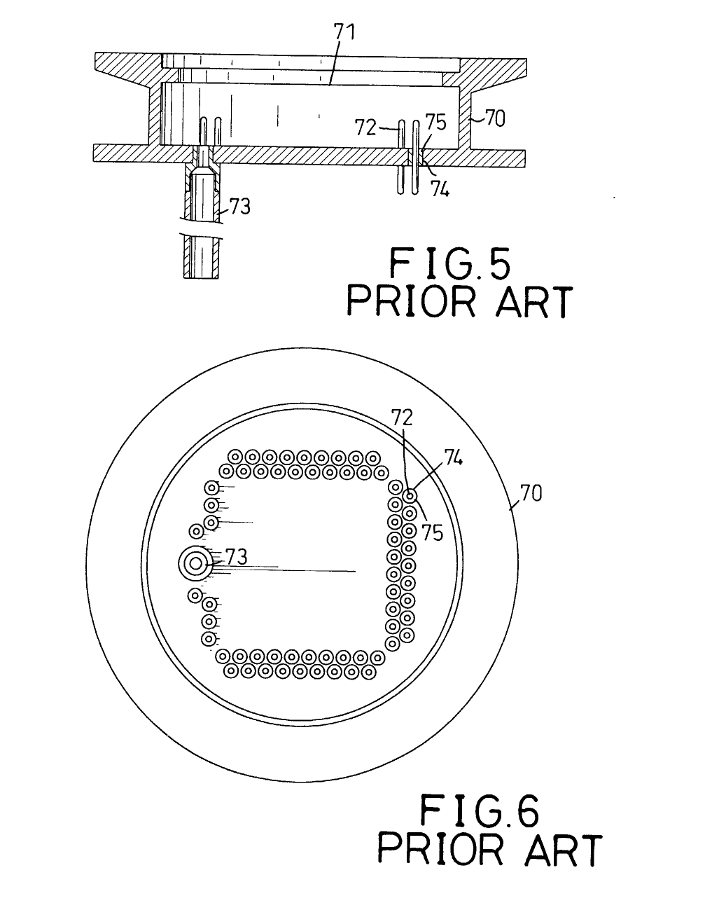

With reference to FIGS. 3 and 4, in accordance with the construction of the preferred embodiment, the bottom plate (20) of the cylindrical body (10) is formed of a non-conducting ceramic material, so that the metallic connecting pins (30) can be soldered directly into the through holes (21, 22) of the ceramic bottom plate (20) without any intermediate medium, thus substantially reducing the number of contact surfaces between the metallized through holes (21, 22) and the connecting pins (30). By the conventional way, the connecting pins (30) have to be sealed into the through holes with fritted glass. In the present invention, the chances of developing air gaps between two different kinds of connecting materials during thermal expansion are greatly reduced.

Since the bottom plate (20) is seal welded onto the cylindrical body (10) along the opening edges, and the bottom plate (20) is made of sintered ceramic material, the heat conductance of the ceramic material is generally better than Kovar alloy, thereby providing more efficient heat dissipation for the integrated device in the cavity.

The present invention is advantageous in that (1) the chance of developing air gaps is reduced in proportion to the contact surfaces, since the connecting pins are soldered directly onto the bottom plate; and (2) the heat dissipation of ceramic material is generally better than alloy metal.

The foregoing description of the preferred embodiments of the present invention is intended to be illustrative only and, under no circumstances, should the scope of the present invention be so restricted.

What is claimed is:

1. A modified construct of testing fixture to improve hermetic seal comprises:
a cylindrical body made of Kovar alloy possessing a hollow central portion and two mouth openings respective at a top and a bottom of the cylindrical body;
a round bottom plate made of insulated material placed over a bottom opening of the cylindrical body; wherein the surface of the bottom plate has multiple metallized through holes, through which metal connecting pins are inserted in positions corresponding to internal circuits of integrated devices; and
a round cover plate placed over a top opening of the cylindrical body.

2. The modified construct of testing fixture to improve hermetic seal as claimed in claim 1, wherein the bottom plate has multiple ground lines distributed over a surface and perimeter, being connected to a common ground; wherein one of the ground lines on the surface is being connected to a through hole through which a connecting pin is inserted thus forming a grounding terminal.

3. The modified construct of testing fixture to improve hermetic seal as claimed in claim 2, wherein the bottom plate has a metallized shielding zone created over central area surrounded by the connecting pins, the position of which corresponds to the internal circuits of an integrated device to be loaded into the cylindrical body, and the shielding zone is connected to a ground line to form a protective shielding for the integrated device against electromagnetic interference.

4. The modified construct of testing fixture to improve hermetic seal as claimed in claim 3, wherein the bottom plate has at least one metallized through hole reserved for installation of a metallic gas nozzle.

5. The modified construct of testing fixture to improve hermetic seal as claimed in claim 4, wherein the bottom plate is formed of sintered ceramic material.
